(19) United States
(12) Patent Application Publication
(10) Pub. No.: US 2024/0421083 A1
(43) Pub. Date: Dec. 19, 2024

(54) SEMICONDUCTOR DEVICE AND METHOD OF MANUFACTURING THE SAME

(71) Applicant: Kioxia Corporation, Tokyo (JP)

(72) Inventor: Tatsuya KOGISO, Nagoya Aichi (JP)

(73) Assignee: Kioxia Corporation, Tokyo (JP)

(21) Appl. No.: 18/735,195

(22) Filed: Jun. 6, 2024

(30) Foreign Application Priority Data
Jun. 19, 2023 (JP) 2023-100352

(51) Int. Cl. H01L 23/528; H10B 41/20

(52) U.S. Cl. CPC H01L 23/5283; H10B 41/20

(57) ABSTRACT

In one embodiment, a semiconductor device includes a first insulator, and a first interconnect including a first layer that is provided on side and upper faces of the first insulator in the first insulator, and includes a first element as a metal element, and a second layer that is provided on side and upper faces of the first layer in the first insulator, and includes a second element as a metal element different from the first element, and a third element different from the first and second elements. The second layer includes a first portion, an intermediate region, and a second portion that are provided on the side face of the first layer in order. A concentration of the third element in the intermediate region is higher than that of the third element in the first portion, and that of the third element in the second portion.

### CROSS REFERENCE TO RELATED APPLICATION

This application is based upon and claims the benefit of priority from the prior Japanese Patent Application No. 2023-100352, filed on Jun. 19, 2023, the entire contents of which are incorporated herein by reference.

### FIELD

Embodiments described herein relate to a semiconductor device and a method of manufacturing the same.

### BACKGROUND

In forming an interconnect that includes a plurality of layers, it may cause a problem that atoms in a layer are diffused into another layer. For example, metal atoms in a barrier metal layer may be diffused into an interconnect material layer.

### BRIEF DESCRIPTION OF THE DRAWINGS

FIG. 1 is a cross-sectional view showing the structure of a semiconductor device of a first embodiment;

FIG. 2 is an enlarged cross-sectional view showing the structure of the semiconductor device of the first embodiment;

FIGS. 3 and 4 are cross-sectional views showing a method of manufacturing the semiconductor device of the first embodiment;

FIG. 5 is a cross-sectional view showing the structure of the semiconductor device of the first embodiment;

FIGS. 6A to 7C are cross-sectional views showing the method of manufacturing the semiconductor device of the first embodiment;

FIGS. 8A to 8C are cross-sectional views showing a method of manufacturing a semiconductor device of a comparison example of the first embodiment;

FIG. 9 is a graph showing properties of the semiconductor device of the first embodiment;

FIG. 10 is another graph showing properties of the semiconductor device of the first embodiment;

FIG. 11 is another graph showing properties of the semiconductor device of the first embodiment;

FIG. 12 is another graph showing properties of the semiconductor device of the first embodiment;

FIG. 13 is a cross-sectional view showing the structure of a semiconductor device of a second embodiment;

FIGS. 14A to 15B are cross-sectional views showing a method of manufacturing the semiconductor device of the second embodiment; and

FIGS. 16A and 16B are cross-sectional views illustrating properties of the semiconductor devices of the second embodiment and a comparison example thereof.

### DETAILED DESCRIPTION

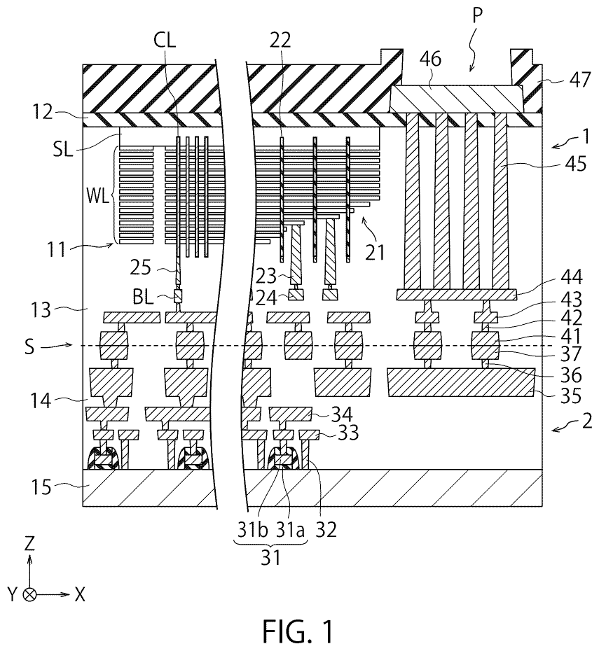

Embodiments will now be explained with reference to the accompanying drawings. In FIGS. 1 to 16B, the same components are given the same reference symbols, and the repeated description will be omitted.

In one embodiment, a semiconductor device includes a first insulator. The device further includes a first interconnect including a first layer that is provided on a side face and an upper face of the first insulator in the first insulator, and includes a first element as a metal element, and a second layer that is provided on a side face and an upper face of the first layer in the first insulator, and includes a second element as a metal element different from the first element, and a third element different from the first element and the second element. The second layer includes a first portion, an intermediate region, and a second portion that are provided on the side face of the first layer in order. A concentration of the third element in the intermediate region is higher than a concentration of the third element in the first portion, and a concentration of the third element in the second portion.

### First Embodiment

FIG. 1 is a cross-sectional view showing the structure of a semiconductor device of a first embodiment.

The semiconductor device of the present embodiment includes a three-dimensional semiconductor memory, for example. As will be described later, the semiconductor device of the present embodiment is manufactured by bonding an array wafer that includes array chips 1 to a circuit wafer that includes circuit chips 2.

The array chip 1 includes a memory cell array 11 that includes a plurality of memory cells, an insulator 12 disposed above the memory cell array 11, and an inter layer dielectric 13 disposed below the memory cell array 11. The insulator 12 is, for example, an SiO₂ film (silicon oxide film). The inter layer dielectric 13 is, for example, a laminated film that includes an SiO₂ film and other insulators.

The circuit chip 2 is provided below the array chip 1. Symbol “S” denotes a bonding face between the array chip 1 and the circuit chip 2. The circuit chip 2 includes an inter layer dielectric 14 disposed below the inter layer dielectric 13, and a substrate 15 disposed below the inter layer dielectric 14. The inter layer dielectric 14 is, for example, a laminated film that includes an SiO₂ film and other insulators. The substrate 15 is, for example, a semiconductor substrate, such as an Si (silicon) substrate.

FIG. 1 shows the X direction and the Y direction parallel to a surface of the substrate 15 and perpendicular to each other, and shows the Z direction perpendicular to the surface of the substrate 15. The X direction, the Y direction, and the Z direction intersect with each other. In DESCRIPTION, the +Z direction is taken as the upward direction, and the −Z direction is taken as the downward direction. The −Z direction may or may not align with the gravity direction.

The array chip 1 includes a plurality of word lines WL as a plurality of electrode layers in the memory cell array 11. FIG. 1 shows a stepped structure portion 21 in the memory cell array 11, and a plurality of beam portions 22 provided in the stepped structure portion 21. Each word line WL is electrically connected to a word interconnect layer 24 via a contact plug 23. Each columnar portion CL that penetrates through these word lines WL is electrically connected to a bit line BL via a via plug 25, and is also electrically connected to a source line SL. The bit line BL is provided below these word lines WL, and the source line SL is provided above these word lines WL.

The circuit chip 2 includes a plurality of transistors 31. Each transistor 31 includes a gate insulator 31a and a gate electrode 31b provided on the substrate 15 in order, and a source diffusion layer and a drain diffusion layer, not shown in the drawing, provided in the substrate 15. The circuit chip 2 also includes a plurality of contact plugs 32 provided on the gate electrodes 31b, the source diffusion layer, and the drain diffusion layer of these transistors 31. The circuit chip 2 also includes an interconnect layer 33, an interconnect layer 34, and an interconnect layer 35. The interconnect layer 33 includes a plurality of interconnects, and is provided on these contact plugs 32. The interconnect layer 34 includes a plurality of interconnects, and is provided above the interconnect layer 33. The interconnect layer 35 includes a plurality of interconnects, and is provided above the interconnect layer 34.

The circuit chip 2 further includes a plurality of via plugs 36 provided on the interconnect layer 35, and a plurality of metal pads 37 provided on these via plugs 36. The metal pads 37 form a metal layer including a Cu (copper) layer, for example. The circuit chip 2 serves as a control circuit (logic circuit) that controls the operation of the array chip 1. This control circuit includes the transistor 31 and other components, and is electrically connected to the metal pads 37.

The array chip 1 includes a plurality of metal pads 41 provided on these metal pads 37, and a plurality of via plugs 42 provided on these metal pads 41. The metal pads 41 form a metal layer including a Cu layer, for example. The array chip 1 also includes an interconnect layer 43 and an interconnect layer 44. The interconnect layer 43 includes a plurality of interconnects, and is provided on these via plugs 42. The interconnect layer 44 includes a plurality of interconnects, and is provided above the interconnect layer 43. The above-mentioned bit line BL is included in the interconnect layer 44. The above-mentioned control circuit is electrically connected to the memory cell array 11 via the metal pads 41, 37, and the like, and controls the action of the memory cell array 11 via the metal pads 41, 37, and the like.

The array chip 1 further includes a plurality of via plugs 45 provided on the interconnect layer 44, and a metal pad 46 provided on these via plugs 45 or the insulator 12. The array chip 1 also includes a passivation insulator 47 provided on the metal pad 46 or the insulator 12. The metal pad 46 is a metal layer including a Cu layer, for example, and serves as an external connection pad (bonding pad) of a semiconductor device of the present embodiment. The passivation insulator 47 is a laminated film that includes, for example, an SiO₂ film and an SiN film (silicon nitride 15 film), and has an opening portion P that causes an upper face of the metal pad 46 to be exposed. The metal pad 46 can be electrically connected to a mounting board or another device by a bonding wire, a solder ball, a metal bump, or the like through the opening portion P.

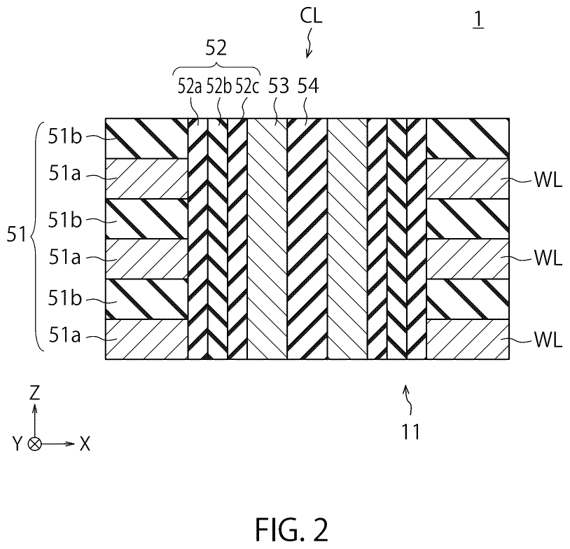

FIG. 2 is an enlarged cross-sectional view showing the structure of the semiconductor device of the first embodiment.

FIG. 2 shows the memory cell array 11 shown in FIG. 1. The memory cell array 11 includes a laminated film 51 that includes a plurality of electrode layers 51a and a plurality of insulators 51b alternately laminated in the Z direction. These electrode layers 51a serve as the above-mentioned word lines WL, for example. Each electrode layer 51a is a metal layer including a W (tungsten) layer, for example. Each insulator 51b is an SiO₂ film, for example.

FIG. 2 also shows one of the plurality of columnar portions CL shown in FIG. 1. Each columnar portion CL includes a memory insulator 52, a channel semiconductor layer 53, and a core insulator 54 provided on a side face of the laminated film 51 in order. The memory insulator 52 includes a block insulator 52a, a charge storage layer 52b, and a tunnel insulator 52c provided on the side face of the laminated film 51 in order. The block insulator 52a is an SiO₂ film, for example. The charge storage layer 52b is, for example, an insulator, such as an SiN film. The charge storage layer 52b may also be a semiconductor layer, such as a polysilicon layer. The tunnel insulator 52c is an SiO₂ film, for example. The channel semiconductor layer 53 is a polysilicon layer, for example. The core insulator 54 is an SiO₂ film, for example.

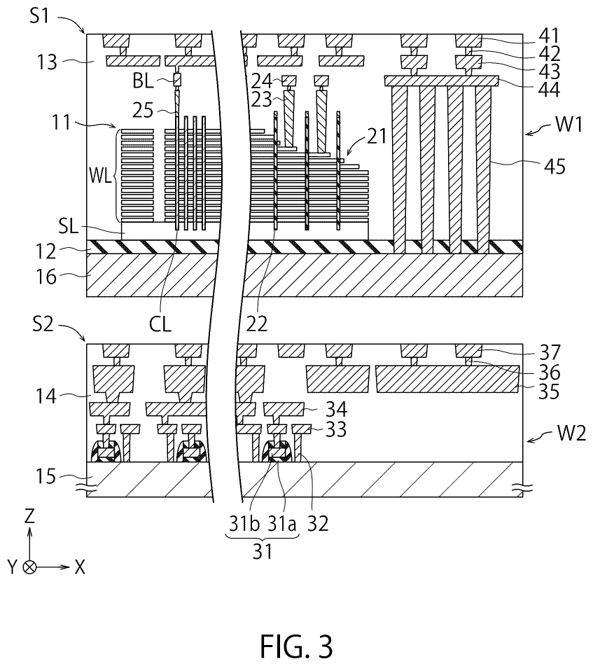

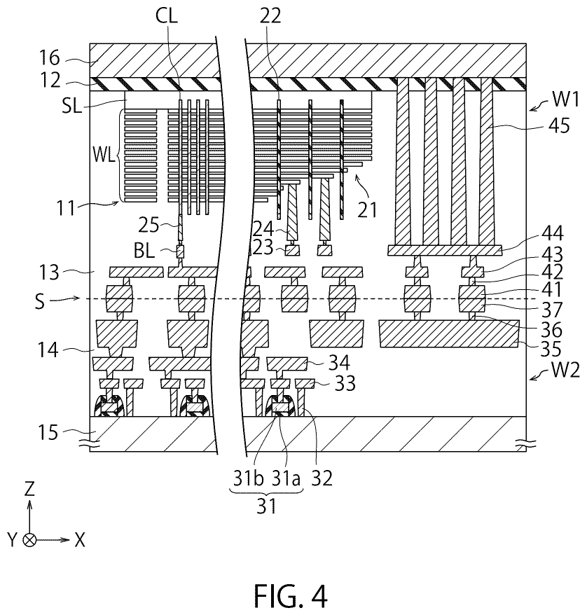

FIGS. 3 and 4 are cross-sectional views showing the method of manufacturing the semiconductor device of the first embodiment.

FIG. 3 shows an array wafer W1 that includes the plurality of array chips 1, and a circuit wafer W2 that includes the plurality of circuit chips 2. In FIG. 3, the direction of the array wafer W1 is opposite to the direction of the array chip 1 in FIG. 1. In the present embodiment, the semiconductor device is manufactured by bonding the array wafer W1 and the circuit wafer W2 to each other. FIG. 3 shows the array wafer W1 before being inverted for bonding, and FIG. 1 shows the array chip 1 after being inverted in direction for bonding, and bonded and diced.

In FIG. 3, symbol “S1” denotes an upper face of the array wafer W1, and symbol “S2” denotes an upper face of the circuit wafer W2. The array wafer W1 includes a substrate 16 provided below the insulator 12. The substrate 16 is, for example, a semiconductor substrate, such as an Si substrate.

In the present embodiment, first, as shown in FIG. 3, the memory cell array 11, the insulator 12, the inter layer dielectric 13, the metal pads 41, and the like are formed above the substrate 16 of the array wafer W1, and the inter layer dielectric 14, the transistors 31, the metal pads 37, and the like are formed above the substrate 15 of the circuit wafer W2. Next, as shown in FIG. 4, the array wafer W1 and the circuit wafer W2 are bonded to each other by mechanical pressure such that the face S1 and the face S2 face each other. With such an operation, the inter layer dielectric 13 and the inter layer dielectric 14 are bonded to each other. Next, the array wafer W1 and the circuit wafer W2 are annealed. With such an operation, the metal pads 41 and the metal pads 37 are joined to each other. In this manner, the substrate 16 and the substrate 15 are bonded to each other through the inter layer dielectrics 13, 14.

Thereafter, the substrate 16 is remove by chemical mechanical polishing (CMP), and the substrate 15 is thinned by CMP and, thereafter, the array wafer W1 and the circuit wafer W2 are cut into a plurality of chips (dicing). The semiconductor device shown in FIG. 1 is manufactured in this manner. The metal pad 46 and the passivation insulator 47 are formed on the insulator 12 after the substrate 16 is removed and the substrate 15 is thinned.

Although FIG. 1 shows an interface between the inter layer dielectric 13 and the inter layer dielectric 14 and interfaces between the metal pads 41 and the metal pads 37, in general, these interfaces cannot be observed after the above-mentioned annealing is performed. However, positions of these interfaces can be estimated by detecting, for example, inclinations of side faces of the metal pads 41 and side faces of the metal pads 37, or positional deviation between the side faces of the metal pads 41 and the side faces of the metal pads 37.

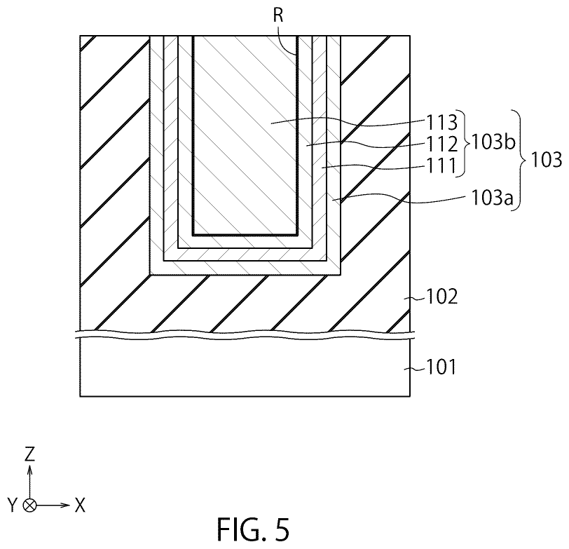

FIG. 5 is a cross-sectional view showing the structure of the semiconductor device of the first embodiment.

As shown in FIG. 5, the semiconductor device of the present embodiment includes a substrate 101, an inter layer dielectric 102 formed on the substrate 101, and an interconnect 103 formed in the inter layer dielectric 102. The interconnect 103 is, for example, a damascene interconnect formed in the inter layer dielectric 102 by single damascene or dual damascene. In FIG. 5, a lower face of the interconnect 103 forms a bottom face of the interconnect 103, and the interconnect 103 is directed upward. The inter layer dielectric 102 is an example of a first insulator. The interconnect 103 is an example of a first interconnect.

For example, the substrate 101 is the substrate 15 in FIG. 1, the inter layer dielectric 102 is the inter layer dielectric 14 in FIG. 1, and the interconnect 103 is an interconnect in the interconnect layer 33, the interconnect layer 34, or the interconnect layer 35 in FIG. 1. In this case, the semiconductor device of the present embodiment includes the inter layer dielectric 13 on the inter layer dielectric 102 (=14), includes the metal pads 37 in the inter layer dielectric 102 (=14), and includes the metal pads 41 in the inter layer dielectric 13 on the metal pad 37. In this case, the inter layer dielectric 14, the inter layer dielectric 13, the metal pad 37, and the metal pad 41 are respectively examples of the first insulator, a second insulator, a first pad, and a second pad.

However, the substrate 101, the inter layer dielectric 102, and the interconnect 103 may respectively be the substrate 15, the inter layer dielectric 13, and the interconnect in the interconnect layer 43 or the interconnect layer 44 in FIG. 1. In this case, the interconnect layers 43, 44 in FIG. 1 are directed downward, but the interconnect 103 in FIG. 5 is directed upward and hence, the direction of the semiconductor device in FIG. 5 is opposite to the direction of the semiconductor device in FIG. 1. Therefore, in this case, the substrate 101 (=15) is not located below the inter layer dielectric 102 (=13), as is shown in FIG. 5, but is located above the inter layer dielectric 102 (=13). In this case, the inter layer dielectric 13, the inter layer dielectric 14, the metal pad 41, and the metal pad 37 are respectively examples of the first insulator, the second insulator, the first pad, and the second pad.

Next, the interconnect 103 will be described in more detail with continuous reference to FIG. 5.

The interconnect 103 includes a barrier metal layer 103a and an interconnect material layer 103b. The barrier metal layer 103a is an example of a first layer. The interconnect material layer 103b is an example of a second layer. The interconnect material layer 103b includes a seed layer 111, a plating layer 112, and a plating layer 113, and also includes a region R located between the plating layer 112 and the plating layer 113. The plating layer 112 is an example of a first portion. The plating layer 113 is an example of a second portion. The region R is an example of an intermediate region.

The barrier metal layer 103a is formed on a side face and an upper face of the inter layer dielectric 102 in the inter layer dielectric 102. The barrier metal layer 103a is a metal layer including, for example, the Ti (titanium) element as a metal element. The barrier metal layer 103a in the present embodiment is a Ti layer. The Ti element is an example of a first element.

The interconnect material layer 103b is formed on a side face and an upper face of the barrier metal layer 103a in the inter layer dielectric 102. The interconnect material layer 103b is a metal layer including, for example, the Cu element as a metal element. The interconnect material layer 103b in the present embodiment is a Cu layer. The interconnect material layer 103b is a metal layer including impurity element, for example. The impurity element is, for example, a non-metal element, such as the C (carbon) element, the N (nitrogen) element, the O (oxygen) element, the S (sulfur) element, or the Cl (chlorine) element. The Cu element is an example of a second element. The impurity element is an example of a third element.

The seed layer 111, the plating layer 112, the region R, and the plating layer 113 are formed on the side face and the upper face of the barrier metal layer 103a in order. The plating layers 112, 113 are formed by performing plating treatment using the seed layer 111, for example. The plating layers 112, 113 in the present embodiment are formed by electro chemical deposition (ECD).

As described above, the interconnect material layer 103b in the present embodiment includes the Cu element and the impurity element. In forming the plating layers 112, 113 by performing the plating treatment, for example, the C element, the N element, the O element, the S element, or the Cl element in a plating solution for the plating treatment enters the interconnect material layer 103b, so that the impurity element is applied to the interconnect material layer 103b. The interconnect material layer 103b in the present embodiment includes the impurity element in the region R at a high concentration. Therefore, a concentration of the impurity element in the region R in the present embodiment is higher than a concentration of the impurity element in the plating layer 112, and is also higher than a concentration of the impurity element in the plating layer 113. For example, the concentration of the impurity element in the region R is five times or more the concentration of the impurity element in the plating layer 112 and/or the concentration of the impurity element in the plating layer 113.

The region R is interposed between the plating layer 112 and the plating layer 113. The thickness of the region R may be set to a small thickness to the extent that the region R cannot be referred to as a layer, or may be set to a large thickness to the extent that the region R can be referred to as a layer. In the former case, the region R may expand with a shape having a thickness close to zero, that is, with a shape close to a plane, between the side face and the upper face of the plating layer 112 and the side face and a lower face of the plating layer 113, for example. In contrast, in the latter case, the region R may be interposed between the plating layer 112 and the plating layer 113 in a state where the thickness is not clear, to be more specific, in a state where the boundary between the plating layer 112 and the region R is not clear, or a state in which the boundary between the plating layer 113 and the region R is not clear, for example. In this case, a portion of the plating layer 112 or a portion of the plating layer 113 may form the region R. In this case, a portion of the plating layer 112 other than the region R is an example of the first portion, and a portion of the plating layer 113 other than the region R is an example of the second portion. The region R will be described later in more detail.

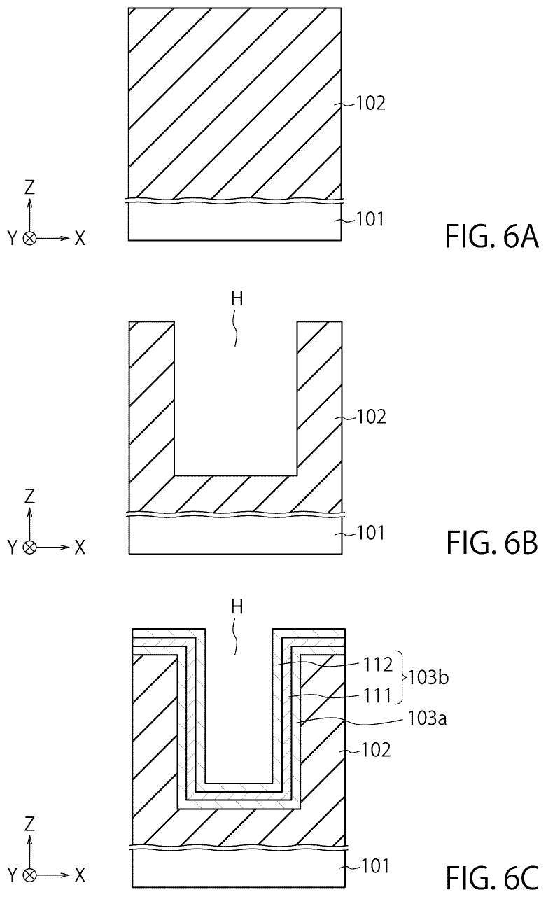

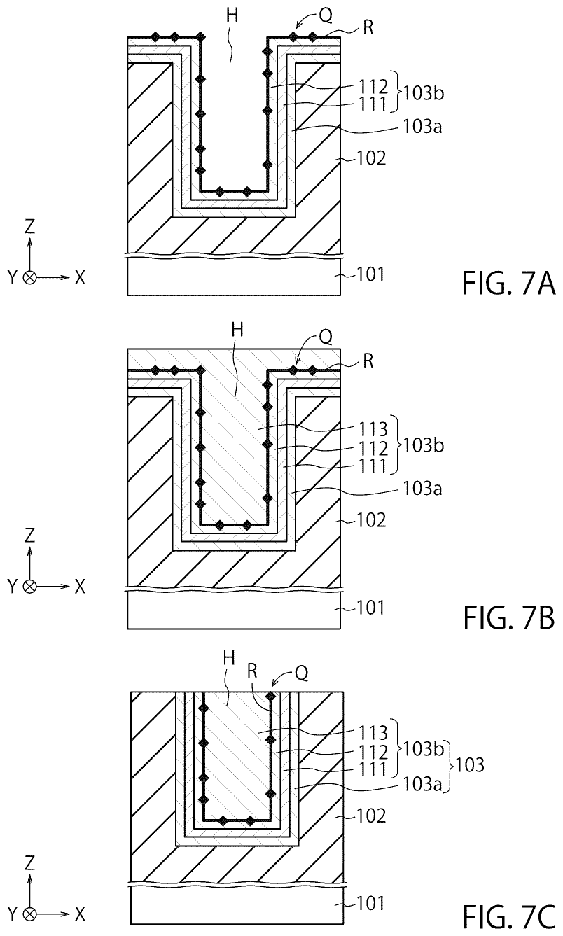

FIGS. 6A to 7C are cross-sectional views showing a method of manufacturing the semiconductor device of the first embodiment.

First, an inter layer dielectric 102 is formed on a substrate 101 (FIG. 6A). Next, a concave portion H is formed in the inter layer dielectric 102 by photolithography and reactive ion etching (RIE) (FIG. 6B). The concave portion H is, for example, an interconnect trench in which an interconnect 103 is embedded.

Next, a barrier metal layer 103a, a seed layer 111, and a plating layer 112 are formed on the entire surface of the substrate 101 in order (FIG. 6C). To be more specific, the barrier metal layer 103a is formed on a side face and an upper face of the inter layer dielectric 102 in the concave portion H, and is formed on an upper face of the inter layer dielectric 102 outside the concave portion H. Further, the seed layer 111 is formed on a side face and an upper face of the barrier metal layer 103a in the concave portion H, and is formed on an upper face of the barrier metal layer 103a outside the concave portion H. In addition, the plating layer 112 is formed on a side face and an upper face of the seed layer 111 in the concave portion H, and is formed on an upper face of the seed layer 111 outside the concave portion H. The plating layer 112 is formed by performing plating treatment using the seed layer 111, for example.

In the plating treatment in the present embodiment, in forming the plating layers 112, 113 by using an electric current, a value of the electric current is set to zero for a certain time. As a result, a predetermined element Q in a plating solution adheres to the surface of the plating layer 112, and thus forming a region R including the element Q at a high concentration on the surface of the plating layer 112 (FIG. 7A). In FIG. 7A, atoms of the element Q are schematically shown by black quadrangular shapes. The region R is, for example, a Cu region that includes the element Q as an impurity element at a high concentration. The region R in the present embodiment is formed on the surface of the plating layer 112 in the concave portion H and outside the concave portion H.

The element Q is, for example, a component element included in an additive in the plating solution. Examples of the element Q include the C element, the N element, the O element, the S element, and the Cl element. In the present embodiment, when the value of electric current for the plating treatment is temporarily set to zero, the element Q in the plating solution is adsorbed to the surface of the plating layer 112. As a result, the region R is formed on the surface of the plating layer 112. An example of the plating solution includes a copper sulfate aqueous solution.

The plating treatment in the present embodiment is performed to include, in order, an energization period, in which the value of the electric current is not zero, a non-energization period, in which the value of the electric current is zero, and an energization period, in which the value of the electric current is not zero. The first energization period, the non-energization period, and the second energization period are respectively examples of a first period, a second period, and a third period. The values of the electric current in the first energization period, the non-energization period, and the second energization period are respectively examples of a first value, a second value, and a third value. The plating layer 112 is formed during the first energization period (FIG. 6C). The region R is formed during the non-energization period and the second energization period (FIG. 7A). The plating layer 113 is formed during the second energization period (FIG. 7B).

In FIG. 7B, the plating layer 113 is formed in the concave portion H and outside the concave portion H, and the concave portion H is filled with the plating layer 113. The interconnect material layer 103b that includes the seed layer 111, the plating layer 112, the region R, and the plating layer 113 in order is formed in this manner. The interconnect material layer 103b in the present embodiment is formed such that a concentration of the element Q in the region R is higher than a concentration of the element Q in the plating layer 112, and is also higher than a concentration of the element Q in the plating layer 113. In the case where the element Q includes multiple kinds of element, such a relationship of concentration may be established for the element Q of each kind, or may be established for the total concentration of the elements Q of all kinds.

The plating layer 113 in the present embodiment is formed by performing the plating treatment that includes a first half period, in which an electric current is set to a small value, and a second half period, in which an electric current is set to a large value. The plating layer 113 in the concave portion H is substantially formed during the first half period, and the plating layer 113 outside the concave portion H is substantially formed during the second half period. The first half period is an example of the third period described above, and the second half period is an example of a fourth period. The value of the electric current in the first half period is an example of the third value described above, and the value of the electric current in the second half period is an example of a fourth value. These periods and current values will be described later in more detail.

Next, the surface of the interconnect material layer 103b is polished by CMP (FIG. 7C). As a result, the interconnect material layer 103b and the barrier metal layer 103a outside the concave portion H are removed, and thus the interconnect 103 is formed in the concave portion H.

Thereafter, subsequent steps for manufacturing the semiconductor device of the present embodiment are performed. As described with reference to FIGS. 3 and 4, for example, an array wafer W1 and a circuit wafer W2 are bonded to each other. The semiconductor device of the present embodiment having the structure shown in FIGS. 1 and 5 is manufactured in this manner.

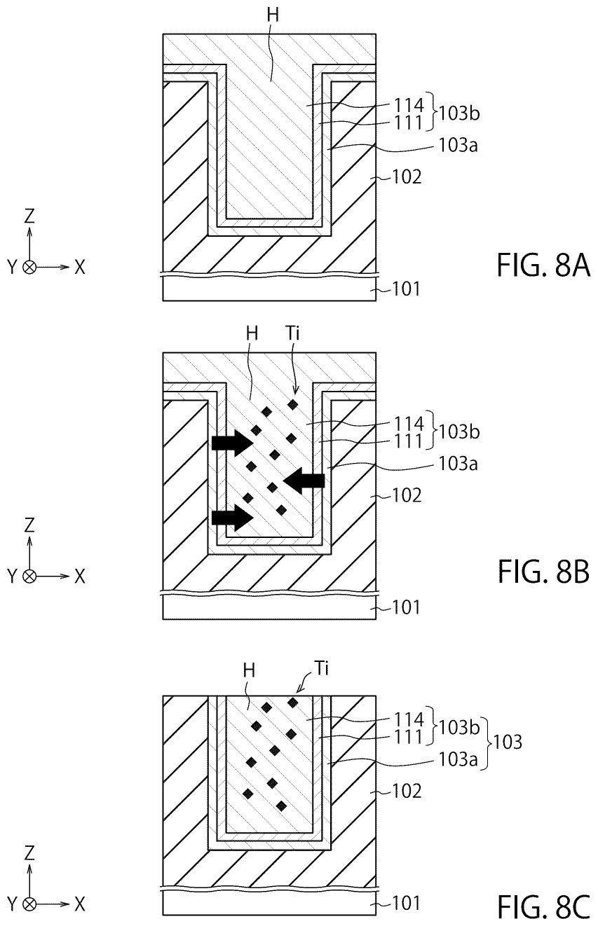

FIG. 8 is a cross-sectional view showing a method of manufacturing a semiconductor device of a comparison example of the first embodiment.

First, an inter layer dielectric 102 is formed on a substrate 101, and a concave portion H is formed in an inter layer dielectric 102 (FIG. 8A). Next, a barrier metal layer 103a, a seed layer 111, and a plating layer 114 are formed on the entire surface of the substrate 101 in order (FIG. 8A). To be more specific, an interconnect material layer 103b that includes a seed layer 111 and a plating layer 114 in order is formed.

The plating treatment in the first embodiment is performed to include the energization period, the non-energization period, and the energization period in order. In contrast, plating treatment in the present comparison example is performed to include only the energization period. As a result, an interconnect material layer 103b in the present comparison example is formed not to include a region R.

In this case, when the barrier metal layer 103a and the interconnect material layer 103b are annealed at a high temperature, there is a possibility that Ti atoms in the barrier metal layer 103a are diffused into the interconnect material layer 103b (FIG. 8B). FIG. 8B schematically shows Ti atoms diffused into the interconnect material layer 103b (the plating layer 114) by a black quadrangular shapes. In this case, electric resistance of an interconnect 103 becomes high (FIG. 8C). In addition, when a semiconductor device is manufactured by bonding an array wafer W1 and a circuit wafer W2 to each other, due to annealing for joining the metal pads 37 and the metal pads 41 to each other, there is a possibility that Ti atoms in the barrier metal layer 103a are diffused into the interconnect material layer 103b.

In contrast, when the barrier metal layer 103a and the interconnect material layer 103b in the present embodiment are annealed at a high temperature, the region R exhibits an effect of suppressing diffusion of Ti atoms. Therefore, the present embodiment makes it possible to suppress a situation in which Ti atoms in the barrier metal layer 103a are diffused into the interconnect material layer 103b. This makes it possible to maintain a low electric resistance of the interconnect 103.

The region R in the present embodiment includes the element Q (impurity element) at a high concentration. As a result, the grain size of crystal grains in the region R is smaller than the grain size of crystal grains in the plating layer 112, and is also smaller than the grain size of crystal grains in the plating layer 113. This causes Ti atoms to be less likely to pass through the region R, thus allowing the region R to suppress diffusion of Ti atoms. The grain sizes of these crystal grains can be measured by observing the interconnect material layer 103b with a scanning electron microscope (SEM), for example.

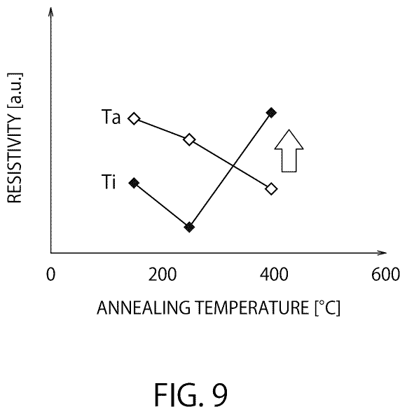

FIG. 9 is a graph showing properties of the semiconductor device of the first embodiment.

The horizontal axis in FIG. 9 shows annealing temperature for a case of annealing the barrier metal layer 103a and the interconnect material layer 103b as described above. The vertical axis in FIG. 9 shows resistivity of the interconnect 103 after being annealed in terms of “a.u.”FIG. 9 shows resistivity of the interconnect 103 for the case where the barrier metal layer 103a is a Ti layer and for the case where the barrier metal layer 103a is a Ta (tantalum) layer.

It can be understood from FIG. 9 that when the barrier metal layer 103a is a Ti layer, resistivity of the interconnect 103 is increased due to annealing at a high temperature. The reason for this is considered to be that Ti atoms are readily diffused in the Cu layer, whereas Ta atoms are less likely to be diffused in the Cu layer.

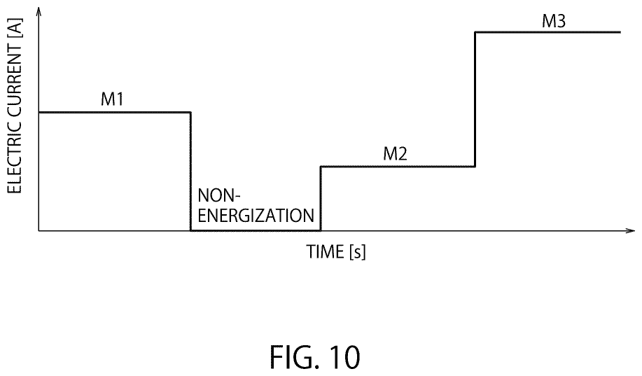

FIG. 10 is another graph showing properties of the semiconductor device of the first embodiment.

FIG. 10 shows variation over time of electric current used in the plating treatment described above. The plating treatment in the present embodiment is performed to include, in order, an energization period, in which the value of the electric current is set to M1, an non-energization period, in which the value of the electric current is set to zero, an energization period, in which the value of the electric current is set to M2, and an energization period, in which the value of the electric current is set to M3. Hereinafter, the energization periods in which the values of the electric current are set to M1, M2, and M3 are respectively referred to as an M1 period, an M2 period, and an M3 period. The M1 period, the non-energization period, the M2 period, and the M3 period are respectively examples of the first period, the second period, the third period, and the fourth period. The current value (M1) in the M1 period, the current value (0) in the non-energization period, the current value (M2) in the M2 period, and the current value (M3) in the M3 period are respectively examples of the first value, the second value, the third value, and the fourth value. In the present embodiment, a relationship of 0<M2<M1<M3 is established for M1, M2, and M3.

In the present embodiment, the plating layer 112 is formed during the M1 period. The region R is formed during the non-energization period and the M2 period. The plating layer 113 is formed during the M2 period and the M3 period. The plating layer 113 in the concave portion H is substantially formed during the M2 period, and the plating layer 113 outside the concave portion H is substantially formed during the M3 period. In general, when the value of an electric current for plating treatment is increased, although the formation rate of a plating layer increases, there is a possibility of deterioration of quality of the plating layer. The present embodiment forms the plating layer 113 in the concave portion H with a small electric current, thus making it possible to increase quality of the plating layer 113 that forms a portion of the interconnect 103. In addition, the present embodiment forms the plating layer 113 outside the concave portion H with a large electric current, thus making it possible to form, within a short time, the plating layer 113 to be removed by CMP.

The length of the non-energization period may be suitably set. However, when the non-energization period is too short, there is a possibility that a sufficient amount of element Q cannot be applied to the region R. In contrast, when the non-energization period is too long, there is a possibility that a plating layer is dissolved due to the non-energization period. In view of the above, the non-energization period in the present embodiment is set within a range of 10 milliseconds to 100 milliseconds, for example. The non-energization period in the present embodiment is set to be shorter than the M1 period, the M2 period, and the M3 period.

The non-energization period may be replaced with an energization period in which the value of the electric current is set to a minute value M. The value of M is 1/10 or less, 1/100 or less, or 1/1000 or less of the value of M2, for example. The present embodiment performs the plating treatment that includes such an energization period, thus making it possible to obtain an advantageous effect substantially equal to an advantageous effect obtained when the plating treatment that includes the non-energization period is performed.

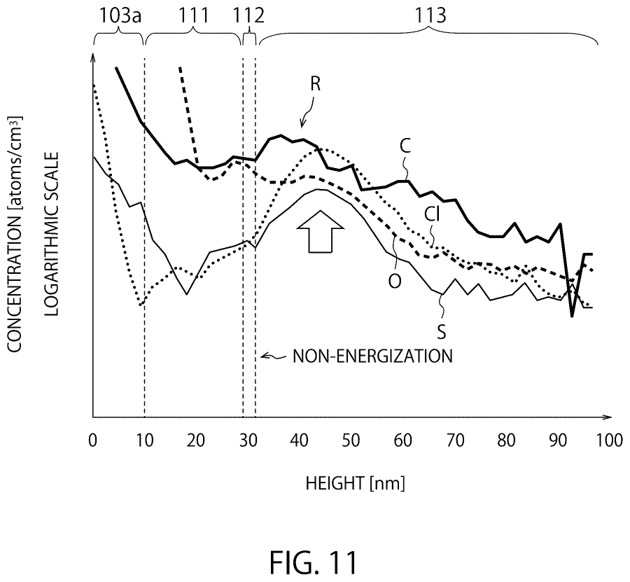

FIG. 11 is another graph showing properties of the semiconductor device of the first embodiment.

The horizontal axis in FIG. 11 shows height (Z coordinate) of respective points in the interconnect 103. The vertical axis in FIG. 11 shows concentration of the element Q (impurity element) at the respective points in the interconnect 103 on a logarithmic scale. FIG. 11 shows concentration profiles of impurity elements in the interconnect 103 for the C element, the O element, the S element, and the Cl element. Heights of the respective points in the interconnect 103 are merely examples. Concentrations of the elements Q (impurity elements) at the respective points in the interconnect 103 are also merely examples.

FIG. 11 shows concentration profiles in the barrier metal layer 103a, the seed layer 111, the plating layer 112, and the plating layer 113. As shown in FIG. 11, the plating treatment in the present embodiment is performed to include the non-energization period after the plating layer 112 is formed. As a result, a concentration of impurity in the plating layer 113 in the vicinity of the plating layer 112 is increased as shown by an outline arrow. In this case, this portion forms the region R in the present embodiment.

In FIG. 11, the concentration of the C element is high in the region R, and the concentrations of the S element and the Cl element are very high in the region R. Therefore, in the case of FIG. 11, it is desirable that the region R include the C element, and it is further desirable that the region R include the S element and the Cl element.

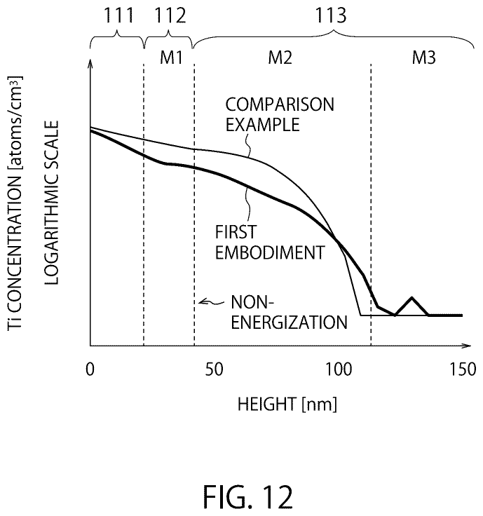

FIG. 12 is another graph showing properties of the semiconductor device of the first embodiment.

The horizontal axis in FIG. 12 shows height (Z coordinate) of respective points in the interconnect 103. The vertical axis in FIG. 12 shows Ti concentration at the respective points in the interconnect 103 on a logarithmic scale. FIG. 12 shows concentration profiles of a Ti concentration in the interconnect 103 in the first embodiment and in the interconnect 103 of the above-mentioned comparison example. Note that “plating layer 112” and “plating layer 113” shown in FIG. 12 are considered to be “plating layer 114” in the comparison example. Heights of the respective points in the interconnect 103 are merely examples. Ti concentrations at the respective points in the interconnect 103 are also merely examples.

It can be understood from FIG. 12 that the Ti concentration in the plating layer 113 formed during the M2 period in the present embodiment, that is, in the plating layer 113 formed in the concave portion H, is lower than that in the comparison example. It can be understood from the above that the present embodiment makes it possible to suppress diffusion of Ti atoms from the barrier metal layer 103a into the interconnect material layer 103b.

As described above, the interconnect 103 in the present embodiment is formed to include the region R between the plating layer 112 and the plating layer 113. Therefore, the present embodiment makes it possible to suppress a situation in which Ti atoms in the barrier metal layer 103a are diffused into the interconnect material layer 103b.

The interconnect 103 in the present embodiment may be an interconnect other than the interconnect in the interconnect layer 33, 34, 35, 43, 44, and may be, for example, contact plugs (contact interconnect), via plugs (via interconnect), or metal pads (pad interconnect). For example, the interconnect 103 in the present embodiment may be any of the contact plugs 32, the via plugs 36, 42, or the metal pads 37, 41.

The barrier metal layer 103a in the present embodiment may include a metal element other than the Ti element. The interconnect material layer 103b in the present embodiment may include a metal element other than the Cu element. The region R in the present embodiment may include an impurity element other than the C element, the N element, the O element, the S element, and the Cl element. The semiconductor device of the present embodiment may be manufactured without bonding the wafers to each other.

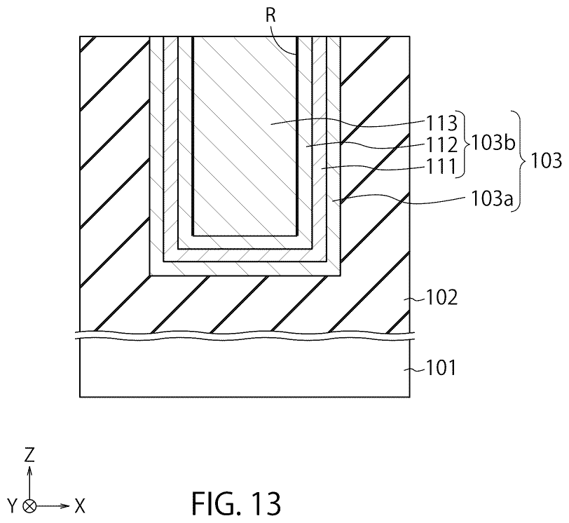

### Second Embodiment FIG. 13 is a cross-sectional view showing the structure of a semiconductor device of a second embodiment.

The semiconductor device (FIG. 13) of the present embodiment has a structure substantially equal to the structure of the semiconductor device of the first embodiment (FIG. 5). However, a region R in the present embodiment is formed at a side portion of a plating layer 112, and is removed from an upper portion of the plating layer 112. As a result, as shown in FIG. 13, a plating layer 113 in the present embodiment includes a portion that faces the plating layer 112 through the region R, and a portion that faces the plating layer 112 through no region R.

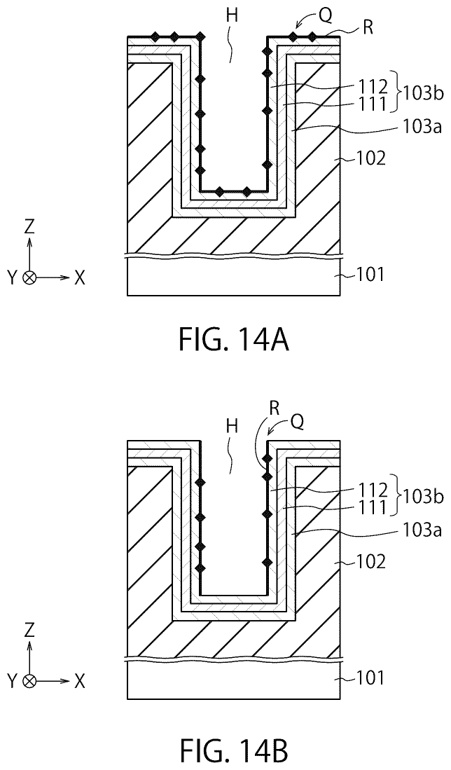

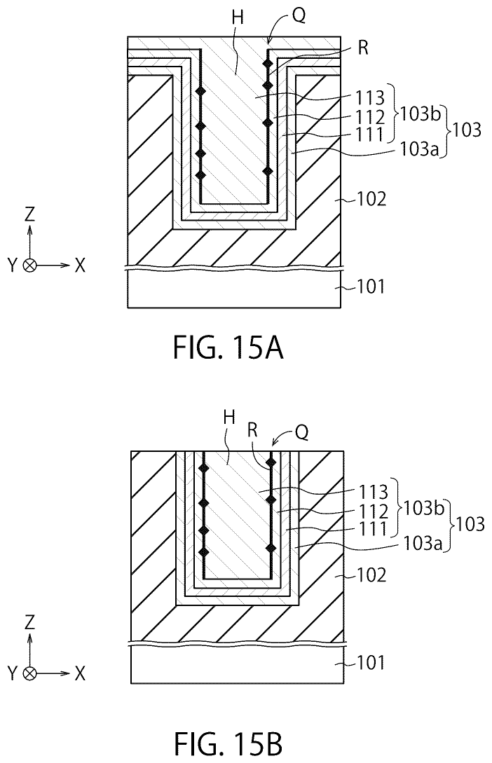

FIGS. 14A to 15B are cross-sectional views showing a method of manufacturing the semiconductor device of the second embodiment.

First, an inter layer dielectric 102 is formed on a substrate 101, and a concave portion H is formed in the inter layer dielectric 102 (FIG. 14A). Next, a barrier metal layer 103a, a seed layer 111, and a plating layer 112 are formed on the entire surface of the substrate 101 in order, and a region R is formed on the surface of the plating layer 112 (FIG. 14A). Steps for FIG. 14A are performed in the same manner as steps in FIG. 6A to 7A.

Next, the region R is removed except for the side portion of the concave portion H by RIE (FIG. 14B). As a result, the upper face of the plating layer 112 is exposed at a bottom portion of the concave portion H. At this point of operation, the plating layer 112 may also be removed except for the side portion of the concave portion H, and thus an upper face of the seed layer 111 may be exposed at the bottom portion of the concave portion H.

Next, a plating layer 113 is formed on the entire surface of the substrate 101 (FIG. 15A). An interconnect material layer 103b that includes the seed layer 111, the plating layer 112, the region R, and the plating layer 113 in order is formed in this manner. The interconnect material layer 103b in the present embodiment is also formed such that a concentration of an element Q in in the region R is higher than a concentration of the element Q in the plating layer 112, and is also higher than a concentration of the element Q in the plating layer 113.

Next, the surface of the interconnect material layer 103b is polished by CMP (FIG. 15B). As a result, the interconnect material layer 103b and the barrier metal layer 103a outside the concave portion H are removed, and thus an interconnect 103 is formed in the concave portion H.

Thereafter, subsequent steps for manufacturing the semiconductor device of the present embodiment are performed. As described with reference to FIGS. 3 and 4, for example, an array wafer W1 and a circuit wafer W2 are bonded to each other. The semiconductor device of the present embodiment having the structure shown in FIGS. 1 and 13 is manufactured in this manner.

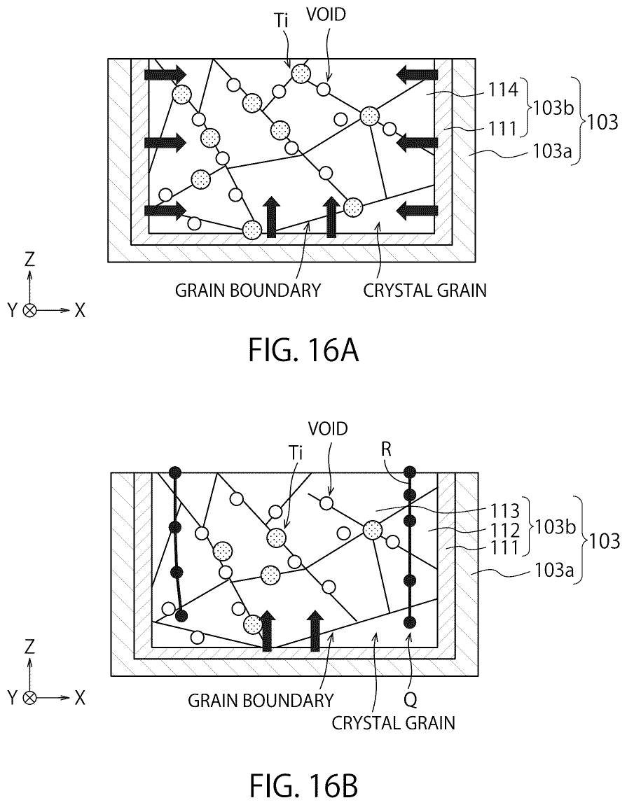

FIGS. 16A and 16B are cross-sectional views illustrating properties of the semiconductor devices of the second embodiment and a comparison example thereof.

FIG. 16A shows the semiconductor device of the comparison example of the present embodiment. The structure of the semiconductor device of the comparison example of the present embodiment is substantially equal to the structure of the semiconductor device of the comparison example of the first embodiment (see FIG. 8C). FIG. 16A schematically shows crystal grains, grain boundaries, voids, Ti atoms, and the like in the plating layer 114.

FIG. 16B shows the semiconductor device of the present embodiment. FIG. 16B schematically shows crystal grains, grain boundaries, voids, Ti atoms, and the like in the plating layers 112, 113 in the same manner as FIG. 16A. FIG. 16B further shows the region R between the plating layer 112 and the plating layer 113, and atoms of the element Q.

The interconnect 103 in the comparison example does not include the region R. Therefore, Ti atoms in the barrier metal layer 103a in the comparison example are not only readily diffused into the plating layer 114 from the barrier metal layer 103a in the vicinity of a bottom face of the interconnect 103, but also readily diffused into the plating layer 114 from the barrier metal layer 103a in the vicinity of the side face of the interconnect 103. However, aggregation of voids in the plating layer 114 can be suppressed by Ti atoms. The reason for that is when Ti atoms enter the plating layer 114, voids are less likely to be formed in the plating layer 114, thus leading to a small number of voids in the plating layer 114. As a result, defects of the interconnect 103 caused by voids are reduced.

In contrast, the interconnect 103 in the present embodiment includes the region R between the plating layer 112 and the plating layer 113 in the vicinity of the side face of the interconnect 103. Therefore, Ti atoms in the barrier metal layer 103a in the present embodiment are readily diffused into the plating layer 113 from the barrier metal layer 103a in the vicinity of the bottom face of the interconnect 103, but are less likely to be diffused into the plating layer 113 from the barrier metal layer 103a in the vicinity of the side face of the interconnect 103. This makes it possible to maintain a low electric resistance of the interconnect 103. Further, the present embodiment makes it possible to suppress aggregation of voids in the plating layer 114 with a small amount of Ti atoms diffused in the plating layer 113. This makes it possible to reduce defects of the interconnect 103 caused by voids.

As described above, the interconnect 103 in the present embodiment is formed to include the region R between the plating layer 112 and the plating layer 113. Therefore, the present embodiment makes it possible to suppress a situation in which Ti atoms in the barrier metal layer 103a are diffused into the interconnect material layer 103b.

The region R in the present embodiment is formed in the vicinity of the side face of the interconnect 103, and is removed from the vicinity of the bottom face of the interconnect 103. Therefore, the present embodiment makes it possible to cause only a small amount of Ti atoms in the barrier metal layer 103a to be diffused into the interconnect material layer 103b. This makes it possible to reduce a disadvantage of Ti atoms (an increase in resistance), and to receive an advantage of Ti atoms (a reduction of the problem of voids).

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions. CLAIMS

1. A semiconductor device comprising:
a first insulator; and
a first interconnect including a first layer that is provided on a side face and an upper face of the first insulator in the first insulator, and includes a first element as a metal element, and a second layer that is provided on a side face and an upper face of the first layer in the first insulator, and includes a second element as a metal element different from the first element, and a third element different from the first element and the second element,
wherein
the second layer includes a first portion, an intermediate region, and a second portion that are provided on the side face of the first layer in order, and
a concentration of the third element in the intermediate region is higher than a concentration of the third element in the first portion, and a concentration of the third element in the second portion.

2. The device of claim 1, wherein the first portion, the intermediate region, and the second portion are provided on the side face and the upper face of the first layer in order.

3. The device of claim 1, wherein the second portion includes a portion that faces the first portion thorough the intermediate region, and a portion that faces the first portion through no intermediate region.

4. The device of claim 1, wherein the first layer is a barrier metal layer in the first interconnect, and the second layer is an interconnect material layer in the first interconnect.

5. The device of claim 1, wherein the first element is Ti (titanium).

6. The device of claim 1, wherein the second element is Cu (copper).

7. The device of claim 1, wherein the third element is C (carbon), N (nitrogen), O (oxygen), S (sulfur), or Cl (chlorine).

8. The device of claim 1, wherein the third element is a non-metal element.

9. The device of claim 1, wherein the second layer is a metal layer that includes the third element as an impurity element.

10. The device of claim 1, wherein the concentration of the third element in the intermediate region is five times or more the concentration of the third element in the first portion and/or the concentration of the third element in the second portion.

11. The device of claim 1, further comprising:
a first pad provided in the first insulator;
a second insulator provided on the first insulator; and
a second pad provided in the second insulator on the first pad.

12. A method of manufacturing a semiconductor device, the method comprising:
forming a first insulator; and
forming a first interconnect including a first layer that is provided on a side face and an upper face of the first insulator in the first insulator, and includes a first element as a metal element, and a second layer that is provided on a side face and an upper face of the first layer in the first insulator, and includes a second element as a metal element different from the first element, and a third element different from the first element and the second element,
wherein
the second layer is formed to include a first portion, an intermediate region, and a second portion that are provided on the side face of the first layer in order, and
a concentration of the third element in the intermediate region is set higher than a concentration of the third element in the first portion, and a concentration of the third element in the second portion.

13. The method of claim 12, wherein
the second layer is formed by plating treatment that is performed by using an electric current, and
the plating treatment is performed to include a first period in which the electric current is set to a first value, a second period in which the electric current is set to a second value smaller than the first value after the first period, and a third period in which the electric current is set to a third value larger than the second value after the second period.

14. The method of claim 13, wherein the third value is smaller than the first value.

15. The method of claim 13, wherein the second value is zero.

16. The method of claim 13, wherein
the first portion is formed during the first period,
the intermediate region is formed during the second period and the third period, and
the second portion is formed during the third period.

17. The method of claim 13, wherein the intermediate region is formed by causing the third element in a plating solution for the plating treatment to adhere to a surface of the first portion.

18. The method of claim 17, wherein the plating solution is a copper sulfate aqueous solution.

19. The method of claim 13, wherein the plating treatment is performed to further include a fourth period in which the electric current is set to a fourth value larger than the third value after the third period.

20. The method of claim 12, further comprising:
forming a first pad in the first insulator;
forming a second insulator;
forming a second pad in the second insulator; and
bonding the first insulator and the second insulator to each other to cause the first pad and the second pad to be bonded to each other.
